(19) United States
(12) Patent Application Publication
(10) Pub. No.: US 2007/0235773 A1
(43) Pub. Date: Oct. 11, 2007

(54) Gas-sensitive field-effect transistor for the detection of hydrogen sulfide

(76) Inventors: Ignaz Eisele, Icking (DE); Maximilian Fleischer, Hohenkirchen (DE); Gunter Freitag, Munchen (DE); Thorsten Knittel, Palhing (DE); Uwe Lampe, Buxethude (DE); Hans Meixner, Haar (DE); Roland Pohle, Herdweg (DE); Elfriede Simon, Munchen (DE)

Correspondence Address: O'SHEA, GETZ & KOSAKOWSKI, P.C., 1500 MAIN ST., SUITE 912, SPRINGFIELD, MA, 01115, US

(21) Appl. No.: 11/396,276

(22) Filed: Mar. 31, 2006

(30) Foreign Application Priority Data
Mar. 31, 2005 (DE) 10 2005 014 768.2

(51) Int. Cl. H01L 23/58

(52) U.S. Cl. 257/253

(57) ABSTRACT

A gas-sensitive field-effect transistor (GasFET) for the detection or measurement of an amount of hydrogen sulfide present in ambient air includes a raised gate electrode and a transistor structure. The raised gate electrode may be formed from or coated with a gas-sensitive material such as tin oxide, or silver, silver oxide or mixtures thereof. An insulator layer may be disposed on top of the transistor structure. An air gap is formed between the gas-sensitive layer of the raised gate electrode and the insulator layer on top of the transistor structure.

### PRIORITY INFORMATION

This patent application claims priority from German patent application 10 2005 014 768.2 filed Mar. 31, 2005, which is hereby incorporated by reference.

### BACKGROUND OF THE INVENTION

The invention relates in general to gas sensors and in particular to a gas sensor for the detection of hydrogen sulfide (H₂S).

The ability to detect or measure the amount of hydrogen sulfide in ambient air is useful due to the toxic properties of the hydrogen sulfide gas. To make these measurements more acceptable, adequate selectivity is preferably combined with sensors of relatively simple design.

Commercially available gas sensors for hydrogen sulfide have generally been based on electrochemical cells which have a relatively short service life, high price, and limited ability to measure high concentrations. Hydrogen sulfide is an inherently highly toxic gas which also smells bad. Values for the typical maximum workplace concentration (MWC) are around 10 vpm, with an instantaneous peak value of 20 vpm. This gas is produced during the decomposition of biological material, for example, the bad odor of liquid manure being attributable in part to hydrogen sulfide. Hydrogen sulfide thus occurs in sewage treatment plants for effluent or in agricultural operations involving factory farms. It is primarily biological in origin and is thus also a component in the primary form of extracted natural gas and of crude oil, with the result that hydrogen sulfide also occurs in refineries. Hydrogen sulfide and sulfides such as sodium sulfide are employed as chemical reagents in a number of industrial processes. One example is the sulfate process for cellulose production.

Due to its relatively low odor threshold, hydrogen sulfide becomes noticeable at relatively low concentrations. Thus, hydrogen sulfide can also be employed as a comparison-standard gas for air quality, for example in the regulation of vehicle air conditioning systems.

For many applications, inexpensive sensors are required which generally handle relatively low threshold values during measurement of hydrogen sulfide, yet with relatively high selectivity and reproducibility. The amount of power required may be low enough to allow for battery operation over a several month period, or by direct connection, for example, to a data bus without auxiliary power.

Due to the safety-related importance and wide area of application for hydrogen sulfide measurements, a large number of different measurement systems are already in use today. For example, the aforementioned relatively sensitive electrochemical cells are employed. However, for many applications the price of these cells is excessive. In addition, sensor systems based on these cells have a relatively high maintenance requirement, while the service life of the individual sensors is relatively short. Metal oxide sensors are found in the lower-price segment. Their reaction to the comparison-standard gas is read out through changes in conductivity. However, these sensors are operated at higher temperatures such as, for example, 200° C. As a result, sensors of this type require considerable power to attain the requisite operating temperature. Thus, sensors of this type are not suitable for many applications such as, for example, fire protection or battery-operated systems, or for direct connection to a data bus. In general, it is has been possible heretofore to employ hydrogen sulfide sensors primarily when an adequate electrical power supply was available.

Due to regulatory requirements, the use of hydrogen sulfide sensors has been continually increasing. At the same time, significant disadvantages have continued to exist due to the high sensor costs resulting in part from the need to supply the sensors with the required operating power. Beyond those applications based on regulatory requirements, hydrogen sulfide sensors have been employed due to the reasons cited, typically when absolutely necessary, for example, for the regulation of devices or equipment, and when the operating power is available at little or no added expense. As soon as these conditions are not met, use of the hydrogen sulfide sensors is generally eliminated, even when such use would be desirable, for example, for reasons of safety.

Gas sensors which utilize as the sensitive measuring principle the change in the electronic work function, or the change in the work function in materials in response to an interaction with the gases to be detected, can be operated at low temperatures and thus with low power consumption. The capability is typically utilized where the change in the work function of gas-sensitive materials is coupled in a field-effect transistor (GasFET) to measure the change in the work function as the change in current between the source and drain of the transistor.

Two types of transistors are typically employed as GasFETs. These are the suspended gate field-effect transistor (SGFET) and the capacitively controlled field-effect transistor (CCFET). Both are characterized by a hybrid design which supports a relatively simple and reliable design principle based on a raised gate electrode utilizing an air gap between the gate electrode and the transistor insulator. The gas-sensitive gate electrode coated with a gas-sensitive material and the actual transistor can be fabricated separately. Flip-chip technology allows the two elements to be combined along with simultaneous relatively precise mutual positioning of the elements. One advantage of this hybrid design technology is the ability to use a multiplicity of materials as the gas-sensitive layer, although these materials due to their dissimilar composition are generally not combinable with, for example, the silicon components of a field-effect transistor. This is true in particular for metal oxides which can be applied using thick-film or thin-film technology.

What is needed is a hydrogen sulfide sensor of simple and cost-effective design which uses relatively low operating power.

### SUMMARY OF THE INVENTION

According to an aspect of the invention, a gas-sensitive field-effect transistor (GasFET) for the detection or measurement of an amount of hydrogen sulfide present in ambient air includes a raised gate electrode and a transistor structure. The raised gate electrode may be formed from or coated with a gas-sensitive material such as tin oxide, or silver, silver oxide or mixtures thereof. An insulator layer may be disposed on top of the transistor structure. An air gap is formed between the gas-sensitive layer of the raised gate electrode and the insulator layer on top of the transistor structure.

A combination of field-effect transistors read out the work function on gas-sensitive layers. The gas-sensitive field-effect transistors have operating temperatures which range between room temperature and 100° C. Certain temperature fluctuations or temperature increases are required to allow reversible changes to proceed. The relatively low operating temperature allows for the inclusion of gas-sensitive layers responding to hydrogen sulfide in a gas sensor which meets varied requirements. Previously, gas-sensitive layers capable of detecting hydrogen sulfide for use in gas-sensitive field-effect transistors were unknown. As tin oxide (SnO₂) has been used in conductivity sensors, tin oxide can be used as a gas-sensitive material for hydrogen sulfide. Also, because silver and silver oxide, or corresponding mixtures thereof, form silver sulfide upon contact with hydrogen sulfide, and since this process is reversible by the addition of heat, it is also possible to employ layers composed of silver, silver oxide, or mixtures thereof, as the gas-sensitive layers. The electrical signals from these material layers can also be evaluated based on the principle of a change in the work function. Connected with this is the fact that silver sulfide possesses a different work function than silver or silver oxide. As a result, the work function difference can be read out using a field-effect-based gas sensor, and this gas signal can then be interpreted.

The possibility of producing the material comprising the gas-sensitive layer from a mixture of different metal oxides has the advantage that numerous and various widely usable gas-sensitive layers of this type are available. These layers can be advantageously produced using thick-film techniques, with a layer thickness of, for example, 5 to 10 μm.

The advantage of lower heat energies based on the use of a field-effect transistor to read out a gas signal by the detection principle described above results from the fact that it is no longer necessary to heat gas-sensitive layers up to, for example, 500° C. or higher to achieve proper operation. The operating temperature range of the gas-sensitive field-effect transistors can be between room temperature and 100° C. or 200° C. This may, however, in certain cases require a heating mechanism to raise the temperature of the transistor to above room temperature.

The areas of application and utilization of hydrogen sulfide sensors are numerous, and it is possible to solve currently relevant problems through the advantageous use of the GasFETs in such fields as vehicle air conditioning systems, indoor air monitoring, battery operation of devices (e.g., mobile devices) and networked systems which coordinate gas sensors through data bus lines.

In particular, the following advantages are provided by the invention: operation with low power consumption, in particular, battery operation or direct connection to data bus lines; small geometric size which facilitates the production and implementation of sensor arrangements; possible monolithic integration of the electronics into the sensor chip; and use of proven inexpensive techniques of semiconductor fabrication to produce a corresponding GasFET.

These and other objects, features and advantages of the present invention will become more apparent in light of the following detailed description of preferred embodiments thereof, as illustrated in the accompanying drawings.

### BRIEF DESCRIPTION OF THE DRAWINGS

FIG. 1 illustrates a GasFET in an embodiment of an SGFET;

FIG. 2 is a cross-section illustration of a CCFET;

FIG. 3 are graphs that illustrate the work function change on a thick film of tin oxide in response to exposure to hydrogen sulfide; and

FIG. 4 is a graph that illustrates the work function change on a silver layer in a hydrogen sulfide sensor at 100° C. and 20% relative humidity.

### DETAILED DESCRIPTION OF THE INVENTION

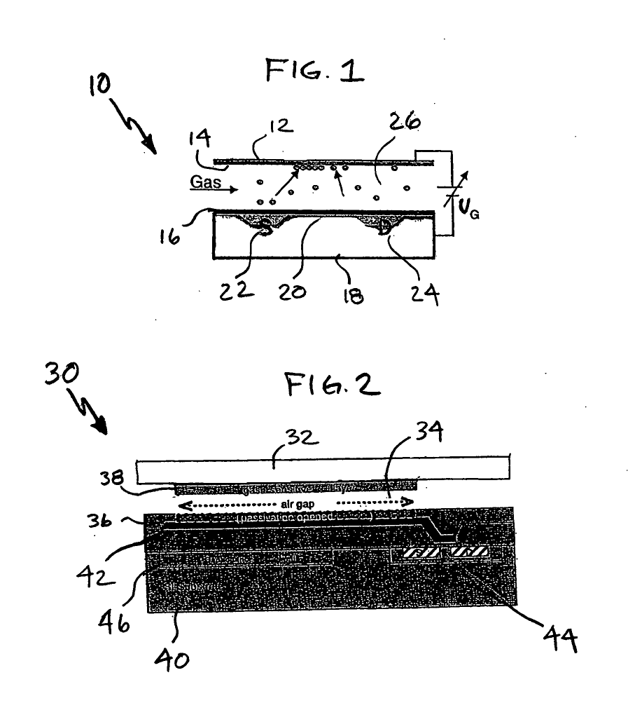

Referring to FIG. 1, a gas sensor 10 includes a raised gate electrode 12 and a gas sensitive layer 14 applied to the underside of the raised gate electrode 12. In the alternative, the gate electrode 12 may be formed from a gas sensitive material similar to that comprising the gas sensitive layer 14. A gate insulator layer 16 is disposed on the base transistor structure 18 composed of a transistor channel 20 and the adjacent source 22 and drain 24 terminals. Thus, an air gap 26 is formed between the gate electrode 12 and the gate insulator layer 16. The illustrated voltage U_{G} is the gate voltage generated in connection with a sensor signal.

FIG. 2 illustrates a CCFET type of gas sensor 30 which also contains a raised gate electrode 32. An air gap 34 analogous to the air gap 26 of FIG. 1 is provided to allow passage of the measured gas. The air gap 34 is bounded by an insulator layer 36 and a gas-sensitive layer 38. The gas-sensitive layer 38 may be applied to the underside of the gate electrode 32, while the insulator layer may be applied to a substrate 40. As in the sensor 10 of FIG. 1, in the alternative the gate electrode 32 may be formed from a gas sensitive material similar to that comprising the gas sensitive layer 38. The potential present in the region of the gas-sensitive layer 38 can be transferred onto the underlying transistor structure. In the CCFET 30 of FIG. 2, a floating gate or floating gate electrode 42 (potential-free electrode) transfers the potential to a laterally displaced read-out transistor 44. A reference electrode 46, also called a capacitance well, shields the floating gate electrode 42.

In response to the presence of the gas to be detected, an electric potential is produced on the gas sensitive layer 14, 38 and this potential corresponds to the change in the work function of the sensitive material that comprises the layer 14, 38. The electric potential is typically between 50 mV and 10 mV. The potential acts on the channel 20 (FIG. 1) of the FET structure and changes the source-drain current. The modified source-drain current is read out directly. Alternatively, the change in the source-drain current is reset by applying an additional voltage to the raised gate electrode 12, 32 or to the transistor well (U_{W}). Here, the additional applied voltage represents the read-out signal which directly corresponds to the work function change in the sensitive layer 14, 38.

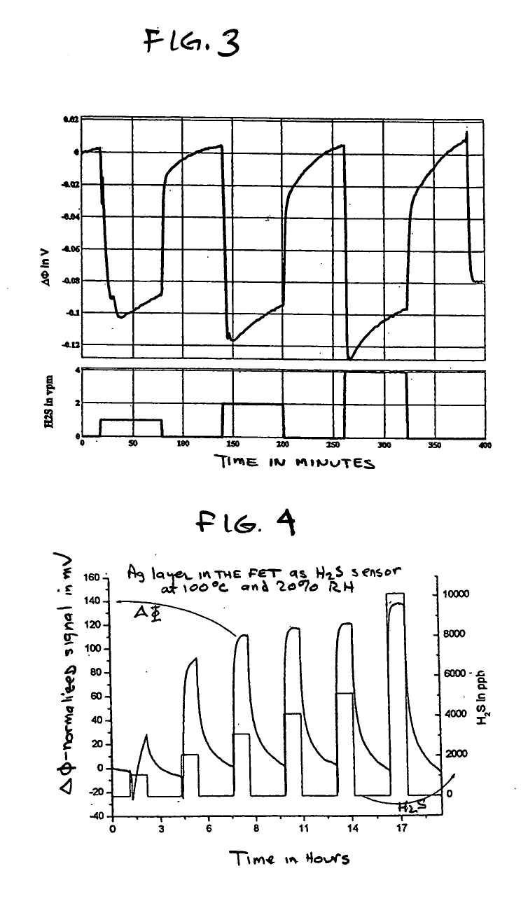

Systems in which hydrogen sulfide is present have in general as their limiting parameter a finite amount of air humidity. Depending on the design, the sensor system may be heated to room temperature or to temperatures up to 100° C. In general, a reversible change in the electron work function is the result, as illustrated in FIGS. 3 and 4. For the relevant gas concentration range of the above-referenced applications, the change in the electron work function ranges between approximately 10 and 100 mV, and is thus sufficiently large to be read out by hybrid-structured gas-sensitive field-effect transistors. As a general rule, the functional principle of the layers indicates results from the existing absorption of molecules to be detected on the metal oxide.

FIG. 3 illustrates a sensor signal over a period of time of 400 minutes. In the lower graph the exposure to hydrogen sulfide is shown in vpm, while in the upper section of the graph the matching sensor signal is illustrated which exactly corresponds as a function of time with the lower quasi on-off-switching operations.

FIG. 4 illustrates a graph in which both a sensor signal and the interval-type exposure to hydrogen sulfide is plotted over time. The applicable conditions for FIG. 4 are that the gas-sensitive layer 14, 38 is composed of silver, the sensor is operated at 100° C., and the relative humidity of the air is 20%.

Some metal oxides especially suitable for detecting hydrogen sulfide thus include tin oxide (SnO₂), or silver, silver-containing material or silver-oxide material. These materials exhibit relatively high stability in diverse environmental conditions. It is also possible to employ mixtures of different metal oxides advantageously, although at least one component of one of the above-indicated materials is typically included along with the others.

The materials may be prepared as gas-sensitive layers, where it is possible to employ cathode sputtering, screen printing, as well as CVD techniques. Typical layer thicknesses may range between 5 and 10 μm. It is advantageous to use a porous open-pored layer composed of one of the above-indicated materials. The preparation of silver, silver-containing, or silver-oxide materials in a gas sensor for the purpose of hydrogen sulfide detection expands the range of materials for gas-sensitive layers which are used in gas-sensitive field-effect transistors. The selective and reproducible signals of these sensors are advantageous in addition to their inexpensive fabrication. Heating of the layer is required in part to enable a return to the original value after impingement by the gas. Operation of the sensor at room temperature displays an integrating response, the reaction in the field-effect transistor being completely reversible from 100° C. At higher temperatures, the signal level is generally reduced.

The functional principle of gas sensors based on FETs is generally known. As a result, inexpensive hydrogen sulfide sensors having a low power requirement are provided by the invention that covers multiple fields of application and uses due to their advantageous properties. Heretofore no material has been highlighted specifically for use as a gas-sensitive layer on a FET sensor.

Measurements taken with a Kelvin probe have been made to confirm the hypothesis that hydrogen sulfide detection is possible at temperatures significantly below the operating temperatures of conductivity sensors. This is achieved by using gas-sensitive field-effect transistors, a special selection of materials being available for the gas-sensitive layer in the form of the tin oxide layer or the layer of silver, silver-containing material, or silver-oxide-containing material.

For tests, a Kelvin probe was fabricated on the basis of a tin oxide thick film which was fired at 600° C. and having a paste composition of 50% by weight tin oxide power and 50% by weight binder (ethyl cellulose/terpinol). Kelvin measurements were performed within the temperature range from room temperature up to 110° C. in humid synthetic air. FIG. 3 illustrates the result at approximately 70° C. for the detection of hydrogen sulfide between 1 and 4 vpm. The measurement demonstrates that hydrogen sulfide can be detected with high sensitivity using this sensitive layer at low temperatures.

Although the present invention has been illustrated and described with respect to several preferred embodiments thereof, various changes, omissions and additions to the form and detail thereof, may be made therein, without departing from the spirit and scope of the invention.

What is claimed is:

1. A gas-sensitive field-effect transistor for the detection of hydrogen sulfide, comprising:
a raised gate electrode having a gas-sensitive layer disposed on a surface thereof, the gas-sensitive layer being sensitive to hydrogen sulfide; and
a transistor substrate having an insulator layer disposed on a surface thereof opposite the gas sensitive layer;
where an air gap is formed between the gas-sensitive layer and the insulator layer, where when hydrogen sulfide is present in the air gap an electrical potential is produced on the gas-sensitive layer in an amount that differs from an amount of the electrical potential when no hydrogen sulfide is present in the air gap.

2. The gas-sensitive field-effect transistor of claim 1, where the gas-sensitive layer comprises one of the materials in the group that includes tin oxide, silver, silver oxide, and a mixture thereof.

3. The gas-sensitive field-effect transistor of claim 1, where the transistor substrate includes source and drain terminals and a channel region, where the amount of the electrical potential present on the gas-sensitive layer acts on the channel region to influence an amount of the electrical current between the drain and source terminals.

4. The gas-sensitive field-effect transistor of claim 3, where the amount of the electrical current between the drain and source terminals is indicative of the amount of hydrogen sulfide present in the air gap.

5. The gas-sensitive field-effect transistor of claim 3, where the source and drain terminals and the channel region are disposed in the transistor substrate underneath the air gap.

6. The gas-sensitive field effect transistor of claim 3, where the source and drain terminals and the channel region are disposed in the transistor substrate laterally away from underneath the air gap.

7. The gas-sensitive field-effect transistor of claim 6, further comprising a floating gate electrode disposed in the transistor substrate at least partially underneath the air gap and at least partially adjacent to the source and drain terminals and the channel region, where the floating gate electrode transfers the amount of electrical potential present on gas-sensitive layer to the channel region.

8. The gas-sensitive field-effect transistor of claim 1, where a thickness of the gas-sensitive layer is between 5 and 10 μm.

9. The gas-sensitive field-effect transistor of claim 1, where the operating temperature of the gas-sensitive layer is adjustable by an electrical heater.

10. The gas-sensitive field-effect transistor of claim 1, where the transistor is installed in a mobile battery-operated device.

11. A gas-sensitive field-effect transistor for the detection of hydrogen sulfide, comprising:
a gate electrode that is sensitive to hydrogen sulfide; and
a transistor substrate having an insulator layer disposed on a surface thereof opposite the gate electrode;
where an air gap is formed between the gate electrode and the insulator layer, where when hydrogen sulfide is present in the air gap an electrical potential is produced on the gate electrode in an amount that differs from an amount of the electrical potential when no hydrogen sulfide is present in the air gap.

12. The gas-sensitive field-effect transistor of claim 10, where the material of the gate electrode comprises one of the materials in the group that includes tin oxide, silver, silver oxide, and a mixture thereof.

13. The gas-sensitive field-effect transistor of claim 11, where the transistor substrate includes source and drain terminals and a channel region, where the amount of the electrical potential present on the gate electrode acts on the channel region to influence an amount of the electrical current between the drain and source terminals.

14. The gas-sensitive field-effect transistor of claim 13, where the amount of the electrical current between the drain and source terminals is indicative of the amount of hydrogen sulfide present in the air gap.

15. The gas-sensitive field-effect transistor of claim 13, where the source and drain terminals and the channel region are disposed in the transistor substrate underneath the air gap.

16. The gas-sensitive field effect transistor of claim 13, where the source and drain terminals and the channel region are disposed in the transistor substrate laterally away from underneath the air gap.

17. The gas-sensitive field-effect transistor of claim 16, further comprising a floating gate electrode disposed in the transistor substrate at least partially underneath the air gap and at least partially adjacent to the source and drain terminals and the channel region, where the floating gate electrode transfers the amount of electrical potential present at the gate electrode to the channel region.

18. A gas-sensitive field-effect transistor for the detection of hydrogen sulfide, comprising:
a raised gate electrode having a gas-sensitive layer disposed on a surface thereof, the gas-sensitive layer being sensitive to hydrogen sulfide; and
a transistor substrate having an insulator layer disposed on a surface thereof opposite the gas sensitive layer, the transistor substrate having source and drain terminals and a channel region;
where the amount of the electrical potential present on the gas-sensitive layer acts on the channel region to influence an amount of the electrical current between the drain and source terminals, where an air gap is formed between the gas-sensitive layer and the insulator layer, where when hydrogen sulfide is present in the air gap an electrical potential is produced on the gas-sensitive layer in an amount that differs from an amount of the electrical potential when no hydrogen sulfide is present in the air gap, where a change in the amount of the electrical potential corresponds to a change in work function of the gas-sensitive layer, and where the gas-sensitive layer comprises one of the materials in the group that includes tin oxide, silver, silver oxide, and a mixture thereof.

19. The gas-sensitive field-effect transistor of claim 18, where the amount of the electrical current between the drain and source terminals is indicative of the amount of hydrogen sulfide present in the air gap.

20. The gas-sensitive field-effect transistor of claim 18, where a thickness of the gas-sensitive layer is between 5 and 10 μm.
